(19) United States
(12) Patent Application Publication
(10) Pub. No.: US 2024/0322523 A1
(43) Pub. Date: Sep. 26, 2024

(54) Systems and Methods for Laser Stabilization

(71) Applicant: The Regents of the University of California, Oakland, CA (US)

(72) Inventors: Daniel J. Blumenthal, Santa Barbara, CA (US); Jiawei Wang, Goleta, CA (US); Kaikai Liu, Santa Barbara, CA (US)

(73) Assignee: The Regents of the University of California, Oakland, CA (US)

(21) Appl. No.: 18/499,768

(22) Filed: Nov. 1, 2023

Related U.S. Application Data
(60) Provisional application No. 63/381,890, filed on Nov. 1, 2022.

(51) Int. Cl. H01S 5/0683

(52) U.S. Cl. CPC H01S 5/0683

(57) ABSTRACT

Systems and methods for photonic integrated laser stabilization that implements one stress-optic modulators in a Pound-Drever-Hall configuration without the complexity or power consumption and loss tradeoffs of conventional bulky acousto-optic modulator (AOM) frequency shifters and electro-optic modulator (EOM) phase modulators are described.

### CROSS-REFERENCE TO RELATED APPLICATIONS

The current application claims the benefit of U.S. Provisional Patent Application No. 63/381,890 entitled “AOM-Free Laser Stabilization Using a Carrier-Tracking Integrated Stress-Optic Modulator” filed Nov. 1, 2022. The disclosure of U.S. Provisional Patent Application No. 63/381,890 is hereby incorporated by reference in its entirety for all purposes.

### STATEMENT OF FEDERALLY SPONSORED RESEARCH

This invention was made with government support under Grant No. W911NF-22-2-0056, awarded by the United States Army and under Grant No. HR0011-22-2-0008, awarded by the Department of Defense/Defense Advanced Research Agency. The government has certain rights in the invention.

### FIELD OF THE INVENTION

The present invention generally relates to methods and systems for laser stabilization; and more particularly to systems and methods for acousto-optic modulator-free and/or electro-optic modulator-free laser stabilization.

### BACKGROUND OF THE INVENTION

As lasers exhibit various types of laser noise, which can be undesirable in applications, suppressing noise and stabilizing certain laser parameters using various techniques may be needed. Stabilized lasers can have improved stability in terms of output power, optical frequency, or other quantities. Laser modulation is the process of changing the optical frequency or phase with time or putting analog or digital information onto the optical carrier or a combination. Modulation can be done by directly varying the current or voltage of a laser over time to change the output signal. Modulation can also be achieved using external modulation where a time varying signal is imposed onto the laser signal after the light is generated. The light generated by the laser prior to modulation can take on many forms, including continuous wave (CW), chirped, and pulsed, among multiple design choices prior to modulation. Electrically driven modulation techniques such as Electro-Optic Modulation (EOM) and Acousto-Optic Modulation (AOM) can be used to manipulate the laser output with electric fields or sound waves. All optical approaches are also possible where an optical signal drives the optical modulator.

An AOM is a device for controlling the transmitted power, direction, or frequency of a laser beam with an electrical drive signal. It uses the acousto-optic effect to diffract the light using sound waves. This diffraction changes the direction of the output light which can then be used for beam steering or controlling the optical intensity. The interaction of the input light to the AOM with the process of scattering changes the optical frequency of the output light. AOMs can be used in lasers for Q-switching, for atomic and quantum experiments, and many other applications where frequency shifting, intensity control, and beam control are required. An EOM is an optical device that uses a signal-controlled element exhibiting an electro-optic effect to modulate a beam of light. The modulation can be applied to the beam's phase, frequency, amplitude, or polarization. AOMs are widely used for many functions in atomic and quantum experiments and in atomic, molecular, and optical (AMO) physics. AOMs are generally bulky, power consuming, and expensive and occupy table space. Therefore, there is a great need to find alternative approaches to realize functions such as laser stabilization, using AOM-free techniques that can be integrated on a chip, reducing the size, weight and cost and improving the reliability of these systems and experiments.

### BRIEF SUMMARY OF THE INVENTION

Methods and systems for AOM-free and EOM-free laser stabilization systems are illustrated.

Some embodiments include a laser stabilization circuit comprising: a tunable laser; a modulator comprising an actuator and a resonator; wherein the modulator is a self-tracking optical modulator; a three-port network comprising a low-frequency DC port, a high-frequency radio-frequency (RF) port, and a combined port; a reference cavity; a voltage-controlled oscillator (VCO); and a first feedback loop and a second feedback loop; wherein the first feedback loop connects with the modulator and applies a feedback signal to the modulator via the low-frequency DC port such that the modulator tracks a resonance of the laser without using an acousto-optic modulator (AOM); wherein the second feedback loop connects with the reference cavity, the modulator, and the VCO; and the high-frequency RF port applies a high-frequency signal to the modulator such that the modulator functions as a double sideband modulator and the laser is Pound-Drever-Hall (PDH) locked to the reference cavity without using an electro-optic modulator (EOM); and wherein the stabilization circuit modulates an output of the tunable laser.

In some embodiments, the modulator is a stress-optic modulator, a thermo-optic modulator, or an electro-optic modulator.

In some embodiments, the resonator is a ring resonator or a phase resonator.

In some embodiments, the ring resonator has a circular shape.

In some embodiments, the three-port network is an electrical network or an electrical optical network.

In some embodiments, the first feedback loop is a proportional integral derivative (PID) loop.

In some embodiments, the second feedback loop is a PID loop.

Some embodiments include a laser stabilization circuit comprising: a tunable laser; a stress-optical modulator comprising an actuator and a ring resonator; a three-port electrical network comprising a low-frequency DC port, a high-frequency radio-frequency (RF) port, and a combined port; a reference cavity; a voltage-controlled oscillator (VCO); and a first proportional integral derivative (PID) loop and a second PID loop; wherein the first PID loop connects with the stress-optical modulator and applies a feedback signal to the stress-optical modulator via the low-frequency DC port such that the stress-optical modulator tracks a resonance of the laser without using an acousto-optic modulator (AOM); wherein the second PID loop connects with the reference cavity, the stress-optical modulator, and the VCO; and the high-frequency RF port applies a high-frequency signal to the stress-optical modulator such that the stress-optical modulator functions as a double sideband modulator and the laser is Pound-Drever-Hall (PDH) locked to the reference cavity without using an electro-optic modulator (EOM); and wherein the stabilization circuit modulates an output of the tunable laser.

In some embodiments, the actuator is laterally and vertically offset from a core of the ring resonator and from an optical mode profile of the ring resonator such that the actuator does not appreciably affect a waveguide loss or a resonator quality factor (Q).

In some embodiments, the core of the ring resonator comprises a material selected from the group consisting of: silicon nitride, tantalum pentoxide, alumina oxide, and aluminum nitride.

In some embodiments, the actuator comprises lead zirconate titanate (PZT) and the ring resonator comprises silicon nitride, and the modulator functions at a wavelength selected from the group consisting of: a visible wavelength range from 400 nm to 750 nm, a near IR wavelength range from 700 nm to 2500 nm, and a mid IR wavelength range from 2500 nm to 25,000 nm.

In some embodiments, the actuator comprises PZT and the ring resonator comprises tantalum pentoxide, alumina oxide, or aluminum nitride, and the modulator functions at a wavelength range selected from the group consisting of: a far-UV wavelength range from 100 nm to 200 nm, a mid-UV wavelength range from 200 nm to 300 nm, a near UV wavelength range from 300 nm to 400 nm, and a visible, near IR and mid-IR wavelength range from 400 nm to 2350 nm.

In some embodiments, the tunable laser is selected from the group consisting of: a semiconductor laser, a stimulated Brillouin scattering (SBS) laser, a PZT-controlled SBS laser, an external cavity laser, a PZT-controlled external cavity laser, a distributed Bragg reflector (DBR) laser, and an external distributed Bragg reflector (EDBR) laser.

In some embodiments, the circuit is compatible with CMOS foundry fabrication process.

In some embodiments, the reference cavity is a coil reference cavity, an ultra-high Q reference cavity, or a miniature bulk micro-optic cavity.

In some embodiments, the coil reference cavity comprises a resonator selected from the group consisting of: a 2-meter on-chip coil resonator, a 4-meter on-chip coil resonator, a 6-meter on-chip coil resonator, an 8-meter on-chip coil resonator, and a 10-meter on-chip coil resonator.

In some embodiments, the ultra-high Q cavity has a Q of at least 40 million.

In some embodiments, a modulation bandwidth of the laser is from 1 kHz to 10 MHz.

Some embodiments include a circuit comprising: a tunable optical frequency comb (OFC); a stress-optical modulator comprising an actuator and a ring resonator; a three-port network comprising a low-frequency DC port, a high-frequency radio-frequency (RF) port, and a combined port; a reference cavity; a voltage-controlled oscillator (VCO); and a first proportional integral derivative (PID) loop and a second PID loop; wherein the first PID loop connects with the stress-optical modulator and applies a feedback signal to the stress-optical modulator via the low-frequency DC port such that the stress-optical modulator tracks a resonance of the OFC without using an acousto-optic modulator (AOM); wherein the second PID loop connects with the reference cavity, the stress-optical modulator, and the VCO; and the high-frequency RF port applies a high-frequency signal to the stress-optical modulator such that the stress-optical modulator functions as a double sideband modulator and the OFC is Pound-Drever-Hall (PDH) locked to the reference cavity without using an electro-optic modulator (EOM); and wherein the circuit modulates an output of the OFC.

In some embodiments, the actuator is laterally and vertically offset from a core of the ring resonator and from an optical mode profile of the ring resonator such that the actuator does not appreciably affect a waveguide loss or a resonator Q.

In some embodiments, the core of the ring resonator comprises a material selected from the group consisting of: silicon nitride, tantalum pentoxide, alumina oxide, and aluminum nitride.

In some embodiments, the actuator comprises lead zirconate titanate (PZT) and the ring resonator comprises silicon nitride, and the modulator functions at a wavelength selected from the group consisting of: a visible wavelength range from 400 nm to 750 nm, a near IR wavelength range from 700 nm to 2500 nm, and a mid IR wavelength range from 2500 nm to 25,000 nm.

In some embodiments, the actuator comprises PZT and the ring resonator comprises tantalum pentoxide, alumina oxide, or aluminum nitride, and the modulator functions at a wavelength range selected from the group consisting of: a far-UV wavelength range from 100 nm to 200 nm, a mid-UV wavelength range from 200 nm to 300 nm, a near UV wavelength range from 300 nm to 400 nm, and a visible, near IR and mid-IR wavelength range from 400 nm to 2350 nm.

In some embodiments, the circuit is compatible with CMOS foundry fabrication process.

In some embodiments, the reference cavity is a coil reference cavity, an ultra-high Q reference cavity, or a miniature bulk micro-optic cavity.

In some embodiments, the coil reference cavity comprises a resonator selected from the group consisting of: a 2-meter on-chip coil resonator, a 4-meter on-chip coil resonator, a 6-meter on-chip coil resonator, an 8-meter on-chip coil resonator, and a 10-meter on-chip coil resonator.

In some embodiments, the ultra-high Q cavity has a Q of at least 40 million.

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

### BRIEF DESCRIPTION OF THE DRAWINGS

The description will be more fully understood with reference to the following figures, which are presented as exemplary embodiments of the invention and should not be construed as a complete recitation of the scope of the invention. It should be noted that the patent or application file contains at least one drawing executed in color. Copies of this patent or patent application publication with color drawing(s) will be provided by the Office upon request and payment of the necessary fee.

FIG. 1 illustrates a photonic integrated circuit of AOM-free and EOM-free stabilized tunable laser in accordance with an embodiment of the invention.

FIG. 2A illustrates a photonic integrated circuit of AOM-free and EOM-free stabilized semiconductor laser in accordance with an embodiment of the invention.

FIG. 2B illustrates a photonic integrated circuit of AOM-free and EOM-free stabilized stimulated Brillouin scattering (SBS) laser in accordance with an embodiment of the invention.

FIG. 2C illustrates a photonic integrated circuit of AOM-free and EOM-free stabilized PZT-controlled SBS laser in accordance with an embodiment of the invention.

FIG. 2D illustrates a photonic integrated circuit of AOM-free and EOM-free stabilized PZT-controlled external cavity laser in accordance with an embodiment of the invention.

FIG. 2E illustrates a photonic integrated circuit of AOM-free and EOM-free stabilized distributed Bragg reflector (DBR) laser in accordance with an embodiment of the invention.

FIGS. 3A and 3B illustrate characterization of frequency noise of the integrated and stabilized semiconductor laser in accordance with an embodiment of the invention.

FIG. 4 illustrates the frequency noise of the free-running and stabilized semiconductor laser with simulated thermo-refractive noise in the reference cavity in accordance with an embodiment of the invention.

FIG. 5A illustrates tracking performances of an AOM-free photonic integrated stabilization in accordance with an embodiment of the invention.

FIG. 5B illustrates laser stabilization with PZT sideband modulation of an AOM-free photonic integrated stabilization in accordance with an embodiment of the invention.

FIG. 6A illustrates an SBS laser photonic integrated circuit layout in accordance with an embodiment of the invention.

FIG. 6B illustrates an integration mask design for an SBS laser at 1550 nm in accordance with an embodiment of the invention.

FIG. 7 illustrates an integration mask design for an SBS laser at 698 nm in accordance with an embodiment of the invention.

FIG. 8 illustrates a mask design for a thermo-optic modulator for laser stabilization in accordance with an embodiment of the invention.

### DETAILED DESCRIPTION

High spectral purity lasers can be important for many applications including precision spectroscopy, precision metrology, atomic clocks, frequency synthesis, quantum computing and sensing, optical gyroscopes, and fiber optic links and communications and fiber sensing. These systems may employ table top lasers, optics and optical reference cavities and racks of electronics to build a stabilized laser. Such systems can achieve ultra-high optical stability (frequency stabilization) and ultra-low phase or frequency noise (noise reduction or linewidth reduction) by employing table-top lasers, free-space optics, bulk acousto-optic modulators (AOMs), electro-optic modulators (EOMs) and table-top reference cavities configured with locking circuits such as the Pound-Drever-Hall (PDH) locking circuit. Many laser stabilization schemes employ combinations of AOMs and EOMs to stabilize the laser to a reference cavity and to stabilize the laser to atomic and quantum transitions.

Conventionally, the AOM, which performs the function of an optical frequency shifter and for intensity control is used in stabilized lasers. The optical frequency shifter can be used in stabilized lasers to adjust the laser output to align with, and to be locked to the optical reference cavity and to align the output of the laser to an atomic or quantum transition. With stabilization, the output of the AOM is a combination of the noise and stability characteristics of the reference cavity and the laser. Additionally, the AOM provides for frequency shifting the stabilized laser light to a desired optical frequency that may be determined by an atomic or quantum qubit transition, atomic clock transition, quantum computer operation, or other spectroscopic requirements and functions. AOMs might be needed for tunable external cavity lasers, as they are less widely tunable compared to semiconductor lasers and direct current locking might not give the external cavity enough tuning range. The EOM, which performs phase modulation to add sidebands to the laser carrier, is also necessary for PDH and other locking schemes. EOMs might be needed for phase modulation for semiconductor lasers as it can be hard to apply strong sidebands for PDH locking by directly modulating the laser due to current sensitivity. However, AOMs and EOMs can be bulky, expensive, and power consuming, and difficult to integrate using photonic integration. AOMs also consume power of greater than 1 watt and can have limited frequency shift ranges (from about-100 MHz to about 100 MHz). There is an increase desire to integrate stabilized lasers and other systems that use stabilized lasers and AOMs onto photonic integrated circuits (PICs) to reduce cost, power consumption, weight and overall size and even to enhance the performance.

Miniaturization of stabilized lasers and other systems that employ AOMs and EOMs can reduce the size, cost, weight and broaden the applications. Miniaturization of stabilized lasers can be achieved using a bulk micro-optic cavity to realize a 25 Hz integral linewidth or using an integrated coil-resonator reference cavity to realize a 36 Hz integral linewidth. (See, e.g., W. Zhang, et al., Laser & Photonics Reviews, 14, 1900293 (2020); K. Liu, et al., Optica, OPTICA, 9, 770-775 (2022); the disclosures of which are incorporated herein by references.) While these demonstrations reduce the reference cavity size, they utilize the bulky, expensive, and power consuming AOM in combination with an EOM to generate the tunable sideband modulated carrier that is needed to stabilize the laser to the cavity. In order to reduce the size, cost and power consumption of the stabilized laser system, the AOM and EOM functionality would need to be realized in a high-performance photonic integrated circuit (PIC) technology. Ultra-low loss waveguide platforms including (but not limited to) silicon nitride (Si₃N₄) waveguide platform can be a wafer-scale CMOS foundry compatible platform. (See, e.g., D. J. Blumenthal, et al., Proc. IEEE 106, 2209-2231 (2018); the disclosure of which is incorporated herein by reference.) The silicon nitride waveguide platform can be transparent from the visible to infrared (IR) wavelengths (from about 405 nm to about 2350 nm), that can support integration of the laser, low power optical modulator for control and reference cavities, and the complete stabilized laser on-chip. (See, e.g., S. Gundavarapu, et al., Nature Photonics 13, 60-67 (2019); J. Wang, et al., Opt. Express, OE 30, 31816-31827 (2022); the disclosures of which are incorporated herein by references.) However, the frequency shifting function and AOM have proved difficult to integrate. The physical and material properties of Si₃N₄ does not readily support AOM and EOM technology directly. Therefore, new stabilization schemes that can utilize the ultra-low loss waveguides and other desirable Si₃N₄ properties but operate free of the AOM and EOM are needed. In addition, the desired stabilization schemes should also support operation across the wide wavelength range of the visible to IR and down to the UV without affecting waveguide loss and other desirable features of integration.

Many embodiments provide systems and methods for AOM-free laser stabilization using carrier-tracking integrated stress-optic modulators in combination with a tunable laser, tunable narrow linewidth laser, and/or other tunable emitter such as optical frequency combs (OFC). The laser stabilization systems in accordance with various embodiments can lock a laser or other optical source directly to an integrated reference cavity. Several embodiments use a double sideband (DSB) modulator that auto-tracks the laser signal during modulation, and allows the laser to be directly aligned to the reference cavity by laser or comb tuning. Some embodiments integrate ultra-low loss optical waveguide and modulators such as (but not limited to) stress-optic modulators, thermo-optic modulators, and/or electric-optic modulators, in a same platform to enable AOM-free laser stabilization. In many embodiments, laser tuning can be achieved by direct current tuning of the laser, and/or stress-optical or thermal tuning of the laser wavelength or optical frequency comb to lock it to the reference cavity. In a number of embodiments, two functions including (but not limited to) modulator auto-tracking of the lasers and double sideband modulation can be combined to realize a set of features. In the feedback loop, the low frequency component of the laser carrier frequency can be applied to a low frequency electronic signal combiner including (but not limited to) a bias-T combiner. The moderate frequency modulation double sideband drive signal (e.g. for a PDH loop) can be applied to the AC port of the electrical signal combiner and then to the modulator. In this manner, the photonic integrated modulator can provide a modulated signal that is locked to the quadrature point of the reference cavity (the desired lock port) and the same modulator can track the laser as it is aligned and stabilized to the same cavity in accordance with several embodiments.

Many embodiments can use one DSB modulator for integrated stabilized laser without a frequency shifter or an AOM. Contrary to the understandings and expectations of the art, the laser frequency can be directly shifted inside the laser and the modulator can track the output making the system AOM free in accordance with several embodiments, instead of the frequency shifting function occurring using such as an AOM at the laser output. In certain embodiments, the stress optical integrated modulators can be incorporated into a ring modulator and/or inside the laser cavity including (but not limited to) an external laser cavity mirror or the resonator for a Brillouin laser. Thermal tuning or electro-optic tuning of the laser in place of or in addition to stress-optic tuning can also be achieved in accordance with several embodiments. The stress optical integrated modulator can also be incorporated into an integrated optical frequency comb, which can also use thermal tuning or electro-optic tuning in addition to stress-optic tuning. All laser tuning can be realized using any of these or other techniques to yield the desired function for any of the embodiments. Several embodiments use a single DSB amplitude modulator instead of requiring a phase only modulator. Ultra-low loss platforms including (but not limited to) silicon nitride platforms can be integrated with the components including (but not limited to) laser, modulator, splitters, combiners, and reference cavity, onto the same chip.

In many embodiments, stabilization of a tunable laser can be achieved by integrating the laser to a Si₃N₄ waveguide reference cavity using an integrated stress-optic modulator including (but not limited to) Si₃N₄ lead zirconate titanate (PZT)-actuated DSB modulator, without the use of an AOM and EOM. The tunable lasers can be single frequency lasers. Various types of tunable lasers such as (but not limited to) semiconductor lasers, stimulated Brillouin scattering (SBS) lasers, PZT-controlled SBS lasers, pump lasers, external cavity lasers, PZT-controlled external cavity lasers, distributed Bragg reflector (DBR) lasers, and/or external distributed Bragg reflector (EDBR) lasers, can be integrated in the laser stabilization systems. The integrated stress-optic modulator can modulate the laser output without affecting the waveguide loss or the Q of the resonator. The DSB modulator can be utilized in a PDH locking scheme to lock the integrated reference cavity.

In various embodiments, stress-optic modulators comprise actuators and resonators. The actuators can be piezo-electric actuators. The resonators can be ring resonators or phase resonators. The actuators can comprise piezo-electric materials such as (but not limited to) PZT or aluminum nitride. The ring resonators have a core that can be made of materials such as silicon nitride, tantalum pentoxide, alumina oxide or aluminum nitride. Materials such as tantalum pentoxide, alumina oxide or aluminum nitride can achieve a wide band gap modulation where the modulators function at a far-UV range from about 100 nm to about 200 nm, a mid-UV range from about 200 nm to about 300 nm, a near UV range from about 300 nm to about 400 nm, and visible, near IR and mid-IR ranges from about 400 nm to about 2350 nm, and beyond. Modulators with silicon nitride resonators can achieve modulation at a wavelength of a visible wavelength range from about 400 nm to about 750 nm, a near IR wavelength range from about 700 nm to about 2500 nm, and a mid IR wavelength from about 2500 nm to about 25,000 nm.

In certain embodiments, the stress-optic modulators comprise circular piezo-electric actuators and ring resonators. The piezo-electric actuators can be offset from the ring resonators such that a first circular portion of the circular piezo-electric actuator is located on the outside of the ring resonators and a second circular portion of the circular piezo-electric actuator is located on the inside of the ring resonator. The circular piezo-electric actuators can be separated from the ring resonators by a top cladding layer. The circular piezo-electric actuators can change the guiding properties of the ring resonators based on the voltage applied to the circular piezo-electric actuators by inducing strain through the top cladding layer to change the optical properties of the ring resonators.

Various types of reference cavity such as (but not limited to) coil reference cavity, miniature bulk micro-optic cavity, and/or ultra-high quality factor (UHQ) waveguide reference cavity (Q of at least 40 million; of at least 50 million; or of at least 60 million; or of at least 70 million), can be integrated in the laser stabilization circuit. Examples of coil reference cavity include (but not limited to) 2-meter on-chip coil resonator, 4-meter on-chip coil resonator, 6-meter on-chip coil resonator, 8-meter on-chip coil resonator, 10-meter on-chip coil resonator. Such coil reference cavity has a large volume to suppress thermal fluctuations. (See, e.g., U.S. patent application Ser. No. 18/488,860 filed Oct. 17, 2023; the disclosure of which is hereby incorporated by reference.) The stabilization scheme can for example achieve over 4 orders of magnitude frequency noise reduction from about 10 Hz to about 1 kHz, 4.5 times reduction in the 1/TT integral linewidth to about 712 Hz, and close to thermo-refractive noise (TRN) limited performance. The ultra-low power stress-optic modulator and ring-resonator reference cavity can use the same ultra-low loss Si₃N₄ waveguide platform. Si₃N₄ has advantages such as low loss across optical transparency window from visible wavelengths of about 400 nm to telecom wavelengths of about 1550 nm; compatible with CMOS foundry fabrication processes; and compatible with high power. The fabrication processes of the integrated stabilized laser, the modulator, and the ring-resonator are compatible with CMOS foundry processes. The PZT stress-optic modulator has a DC to 15 MHz 3-dB modulation bandwidth, a low optical loss of about 0.03 dB/cm at 1550 nm (or a loss of about 0.3 dB/cm at 780 nm; or a loss of about 0.6 dB/cm at 674 nm; or a loss of about 9 dB/cm at about 461 nm), and ultra-low power consumption of about 20 nW. (See, e.g., U.S. patent application Ser. No. 18/485,173 filed Oct. 11, 2023; the disclosure of which is hereby incorporated by reference.)

In several embodiments, the PZT modulator can be employed as an auto carrier-tracking DSB modulator that simultaneously creates the DSB for the PDH loop error signal generation while tracking the laser carrier output as the laser is aligned and stabilized to the reference cavity. The stabilization scheme in accordance with some embodiments can achieve same functions normally handled with AOM frequency shifting that is conventionally used to align an EOM modulated carrier. In some embodiments, a sinusoidal drive signal can be applied to the high frequency port of an electrical combiner network (bias-T) that drives the PZT actuator, providing a PDH loop error signal used to lock the laser to the reference resonator quadrature point. The low frequency port of the combiner network (bias-T) can be used to drive the modulator to auto-track the laser output in accordance with certain embodiments while the PDH loop reduces the close-to-carrier noise (reducing the integral linewidth) and stabilizes the laser carrier. By incorporating these functions into a single Si₃N₄ platform compatible modulator in the PDH loop, many embodiments provide the inventive realization of laser noise reduction by over 40 dB and close to cavity TRN limit. The components can be fabricated using the Si₃N₄ ultra-low loss waveguide processes. Many embodiments demonstrate all-waveguide, system-on-chip photonic integrated frequency stabilized lasers. The stabilized laser in accordance with some embodiments can be used to combine the narrow fundamental linewidth of integrated SBS lasers or injection locked lasers for high frequency noise reduction with the integrated UHQ reference cavity with PDH locking for low frequency noise reduction in the same ultra-low loss Si₃N₄ platform.

In various embodiments, tuning mechanisms such as thermal, thermo-optic, and electro-optic as well as other tuning mechanisms can be used instead of or combined, or in addition to stress-optic tuning to realize the auto-tracking filter. In several embodiments, thermo-optic tuning utilizes (but not limited to) metal heater tuners with PZT actuators. In some embodiments, electro-optic tuning implements materials such as (but not limited to) lithium niobite (LiN) that utilizes electro-optic effect to modulate waveguides (such as silicon nitride waveguides, silicon nitride resonators) without the bulky optical components such as EOM modulators.

Systems and methods for AOM-free laser stabilization in accordance with various embodiments of the invention are discussed in further detail in the attached appendix.

### AOM-Free Laser Stabilization

Many embodiments provide systems and methods for photonic integrated laser stabilization that implements one stress-optic ring-resonator modulator in a PDH configuration without the complexity or power consumption and loss tradeoffs of conventional bulky AOM frequency shifters and EOM phase modulators. The modulator can be a stress-optic (PZT) integrated Si₃N₄ ring-resonator modulator. In several embodiments, the laser can be directly tuned to the reference cavity using the PDH lock while automatically maintaining double sideband modulation on the tuned laser. The AOM-free stabilized laser has multiple advantages: 1) the PZT-actuated modulator consumes tens of nW in power; 2) the carrier-tracking modulator does not affect the low optical waveguide losses; 3) the offset waveguide stress-optic design supports waveguides that can operate from the visible to the infrared wavelengths, and also down to the ultra-violet (UV) with mask-level or waveguide thickness (or material composition) design changes. The photonic integrated stabilized lasers can have many applications since the PZT stress-optic modulator uses wafer-scale processes that are compatible with the integrated reference cavity and lasers (e.g. an external laser cavity mirror or an SBS resonator laser). These components can be realized using the same fabrication processes, and can impact applications such as fiber optic communications, atomic, molecular and optical (AMO) physics, quantum computing and sensing, and atomic clocks.

In many embodiments, laser stabilization can be achieved by integrating the laser to a Si₃N₄ waveguide reference cavity using a single integrated Si₃N₄ PZT-actuated DSB modulator, without the use of an AOM and EOM. Various types of tunable lasers such as (but not limited to) semiconductor lasers, SBS lasers, PZT-controlled SBS lasers, external cavity lasers, PZT-controlled external cavity lasers, DBR lasers, and EDBR lasers, can be integrated in the laser stabilization systems. The laser modulation bandwidth can be from about 1 kHz to about 10 MHz; or from about 1 kHz to about 10 kHz; or from about 1 kHz to about 100 kHz; or from about 1 kHz to about 1 MHz; or from about 1 kHz to about 10 MHz. As can be readily appreciated, although stress-optic tuning is described, other tuning mechanisms such as thermal and electrooptic and other physical waveguide tuning mechanisms can be employed as appropriate to the requirements of specific applications.

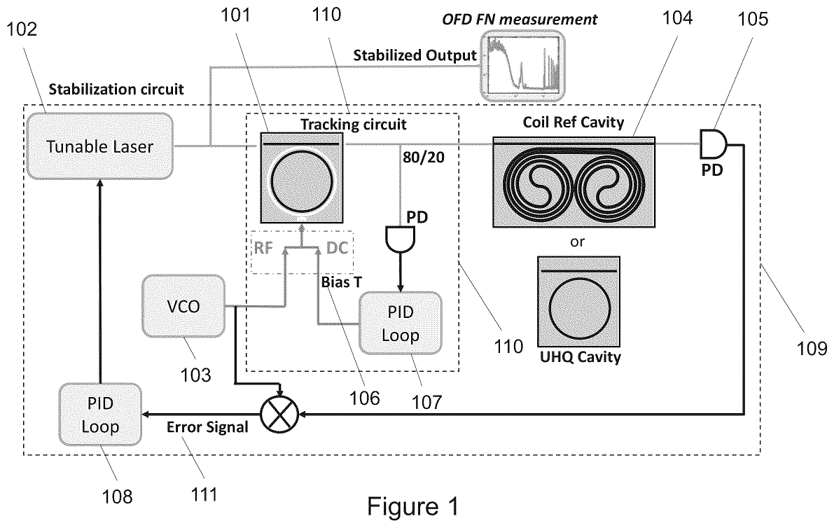

FIG. 1 illustrates a diagram for AOM-free photonic integrated laser stabilization circuit in accordance with an embodiment of the invention. The PZT modulator 101 is locked to a tunable laser carrier 102 in the tracking circuit loop to replace the AOM frequency shifting function. As shown in FIG. 1, the PZT-actuated ring resonator 101 is locked to a tunable laser 102 to perform as an auto-tracking filter by detecting the transmission signal after the PZT resonator and maintaining constant output power by applying a feedback signal to the PZT modulator through the DC/low-frequency port of a bias-T 106, ensuring that the PZT-actuated microresonator resonance maintains alignment with the laser carrier. The PZT modulator 101 can be used as a double sideband modulator to PDH lock the laser carrier to the reference cavity 104 simultaneously, replacing the EOM phase modulation function. The PZT-actuated ring 101 can be used as a DSB modulator by applying a sinusoid amplitude modulated signal via the AC port (RF) of the bias-T 106. This DSB signal is used for PDH locking to the quadrature point of the integrated Si₃N₄ reference cavity such that the laser is stabilized to the quadrature point of the cavity. Thus, the photonic integrated PZT modulator provides sideband modulation for the laser over a wide laser detuning range while the frequency noise of the laser is being reduced and the carrier stabilized to the reference cavity by the PDH loop. The reference cavity 104 can be a coil reference cavity, a miniature bulk micro-optic cavity, or an ultra-high Q (UHQ) cavity. The noise of stabilized laser output can be measured using unbalanced optical frequency discriminator (OFD) fiber-optic delay-line interferometers and balanced photo-detection.

In some embodiments, the PZT actuator can react to both the low frequency signal and the high frequency signal applied via the bias-T. First, a low frequency signal can be applied as an input to the PZT actuator via the DC/low-frequency port of the bias-T 106 (no RF high frequency signal at this moment). The input signal enables the determination of the resonance of the PZT ring 101. The photodetector (PD) 105 detects the resonance (or the transmission signal) of the laser 102. Then a feedback loop for locking such as (but not limited to) a proportional integral derivative (PID) loop 107 that is connected with the PZT actuator can engage the PID locking of the resonance of the laser carrier 102. After the PZT ring resonance is locked to the laser carrier, a high frequency signal can be applied to the PZT actuator as an input signal via the RF port of the bias-T 106. The tracking circuit 110 achieves the modulation function. The error signal 111 of the transmission signal, which is the derivative of the transmission signal, can be calculated. A second feedback loop for locking such as (but not limited to) a PID loop 108 and voltage-controlled oscillator (VCO) 103 can be engaged to lock the laser 102 to the resonance of the reference cavity 104. The applied low frequency signal is independent from the high frequency signal. The tracking circuit loop (inner loop) 110 is independent from the stabilization circuit loop (outer loop) 109. As can be readily appreciated, although PID loop is used as an example in FIG. 1, any type of a feedback loop for locking purposes can be used in the laser stabilization circuit as appropriate to the requirements of specific applications.

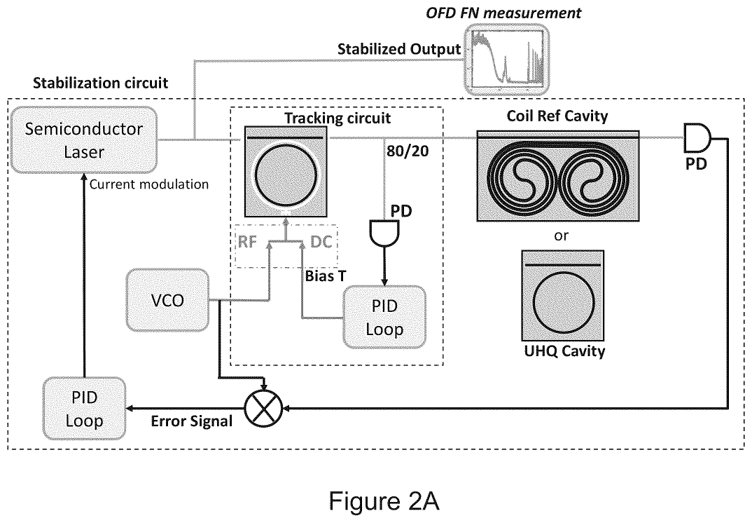

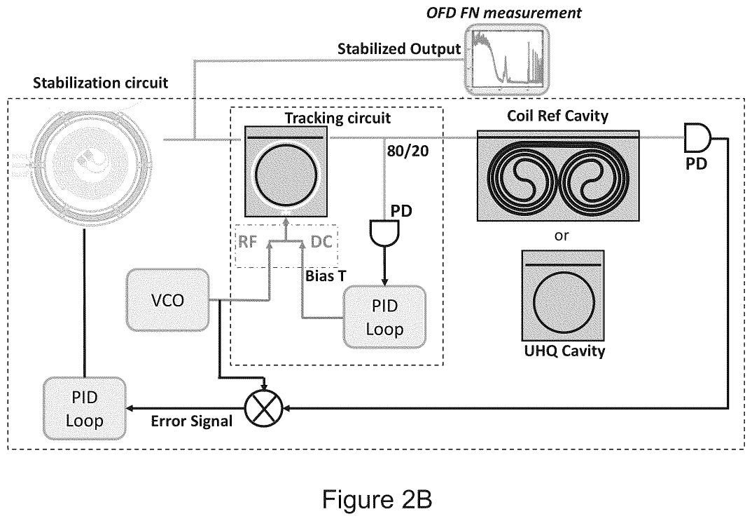

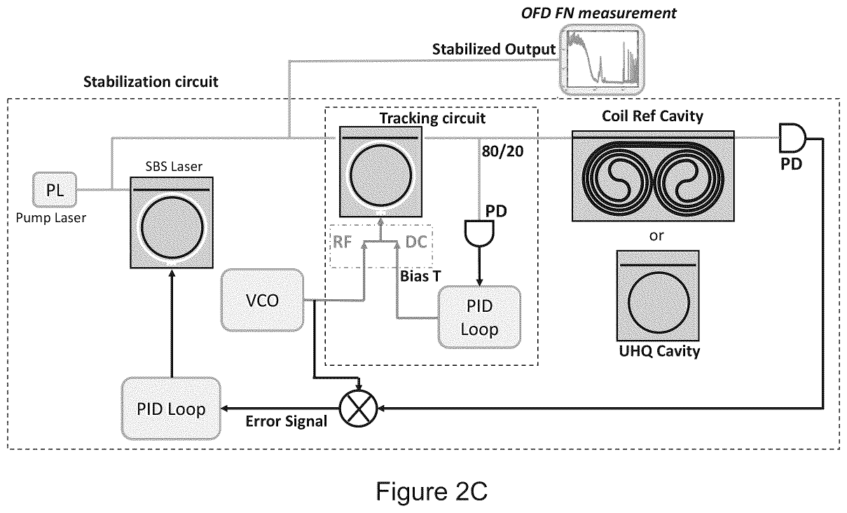

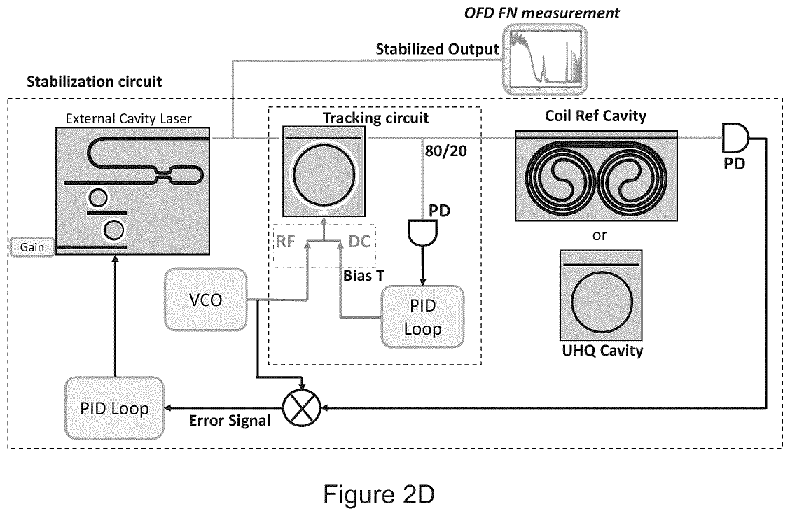

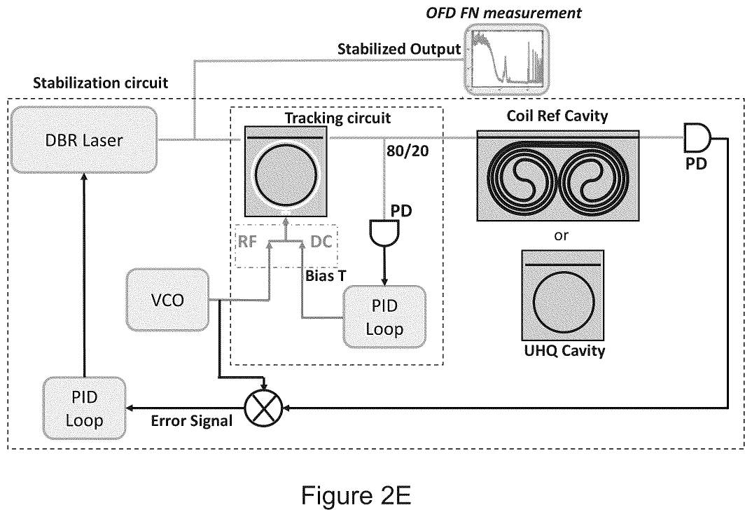

The tunable lasers can be various types of lasers. FIG. 2A illustrates a semiconductor laser integrated in the AOM-free stabilization circuit in accordance with an embodiment. In certain embodiments, the PZT-actuated ring resonator can be locked to a semiconductor laser (Velocity TLB-6700) at a variety of wavelengths such as about 1550 nm. FIG. 2B illustrates an SBS laser integrated in the AOM-free stabilization circuit in accordance with an embodiment. FIG. 2C illustrates a PZT controlled pump laser integrated in the AOM-free stabilization circuit in accordance with an embodiment. FIG. 2D illustrates a PZT controlled external cavity laser integrated in the AOM-free stabilization circuit in accordance with an embodiment. FIG. 2E illustrates a tunable DBR laser integrated in the AOM-free stabilization circuit in accordance with an embodiment.

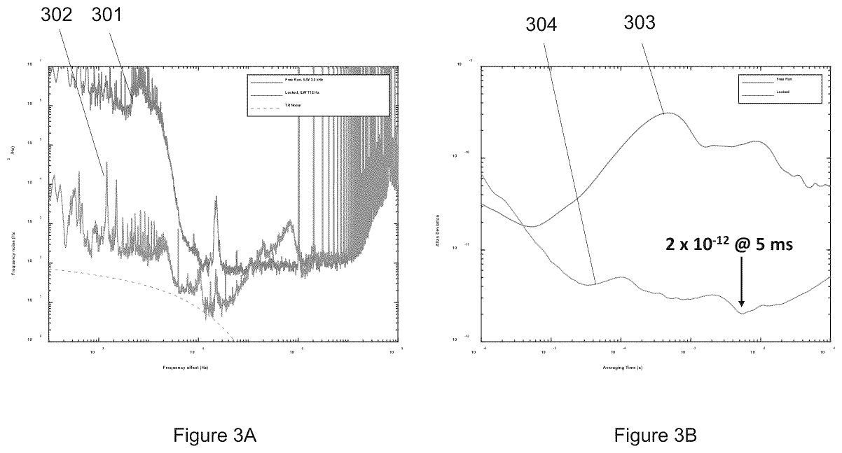

In several embodiments, the frequency noise of the stabilized optical output can be measured using a self-delayed homodyne laser frequency noise method with an unbalanced fiber Mach-Zehnder interferometer (MZI) as the optical frequency discriminator (OFD). FIG. 3A illustrates the frequency noise of the free-running and stabilized semiconductor laser with simulated thermo-refractive noise (TRN) in the reference cavity in accordance with an embodiment of the invention. The resulting frequency noise power spectral density (PSD) is plotted as a function of frequency offset from the laser carrier. Compared to the free running laser (301), the stabilized laser frequency noise (302) is reduced by over 40 dB from about 10 Hz to about 1 kHz frequency offset range and is close to the simulated TRN limit (dashed line) which is intrinsic to the optical mode volume of the reference cavity. The 1/TT integral linewidth is reduced by 4.5 times from 3.2 kHz to 712 Hz. FIG. 3B illustrates the Allan deviation in accordance with an embodiment of the invention. The Allan deviation (ADEV) is a way to view a signal noise over time. The Allan deviation is reduced by over an order of magnitude. The free-running laser (303) has a minimum ADEV of about 1.8×10⁻¹¹ at 5 μs, while the stabilized laser (304) can reach a minimum ADEV of about 2×10⁻¹² at 5 ms.

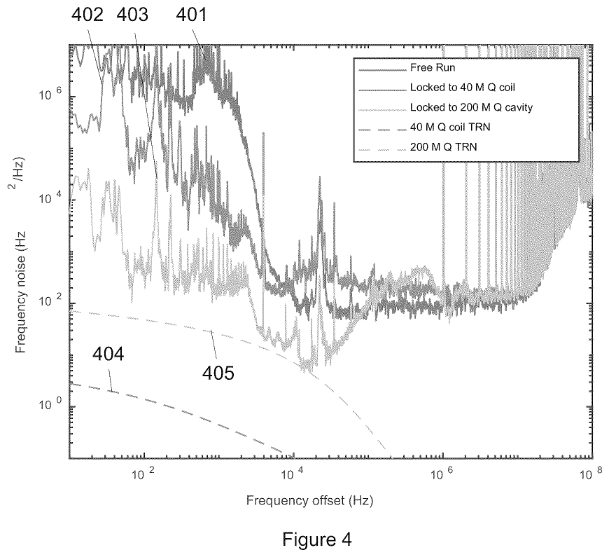

FIG. 4 illustrates the frequency noise of the free-running and stabilized semiconductor laser with simulated thermo-refractive noise (TRN) in the reference cavity in accordance with an embodiment of the invention. FIG. 4 shows the frequency noise of both a coil reference cavity (402) and a UHQ cavity (403). Compared to the free running laser (401), the stabilized laser locked to 40-meter reference cavity (402) and the stabilized laser locked to UHQ reference cavity (403) have lower noise. The frequency noise of the stabilized laser locked to UHQ reference cavity (403) is reduced close to its TRN limit (405). 404 shows the TRN limit of the stabilized laser locked to 40-meter reference cavity (402).

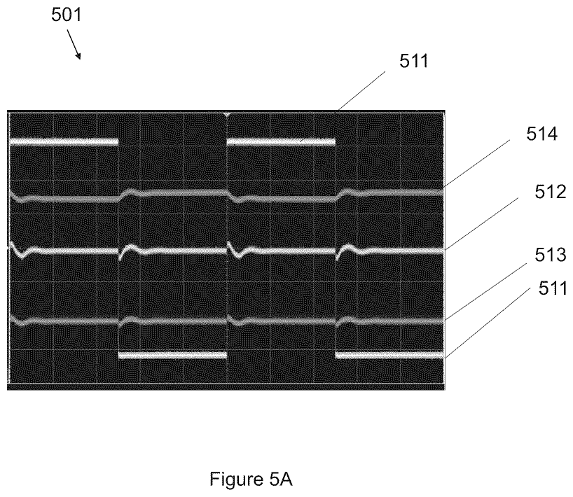

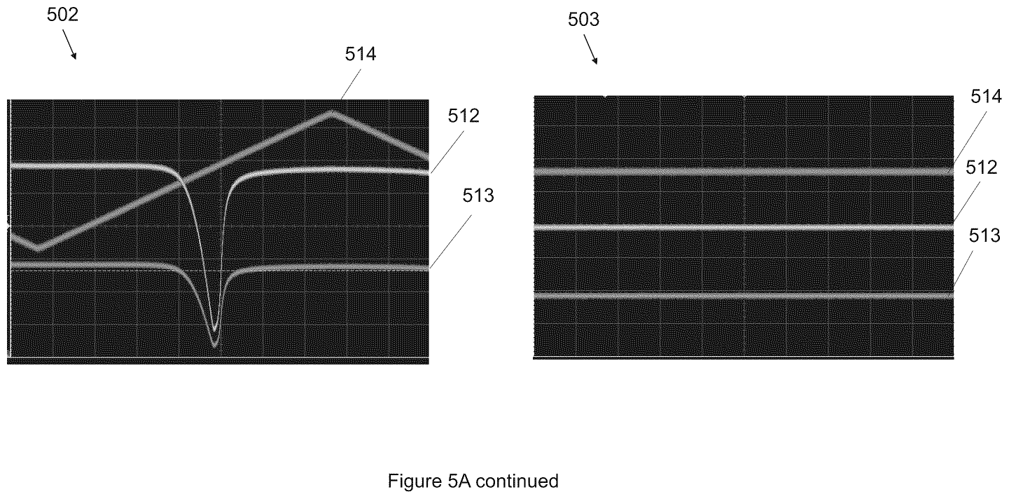

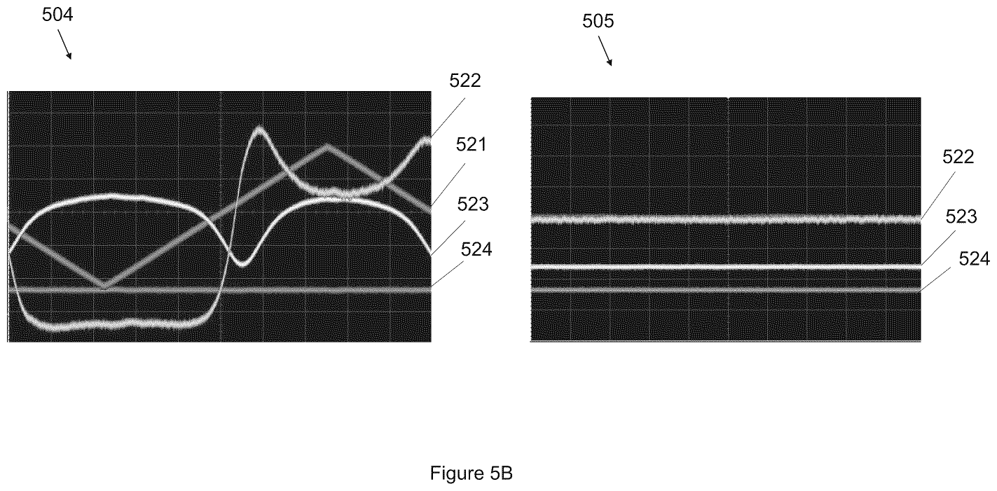

FIG. 5A illustrates tracking performances of an AOM-free photonic integrated stabilization in accordance with an embodiment of the invention. The results are based on the stabilization circuit with a semiconductor laser and a coil reference cavity shown in FIG. 2A. In FIG. 5A, the signal tracking shows an open-loop measurement 501, where an external step function input 511 is added to the laser. The error signal 512 and the transmission signal 513 both react to the step input, and then become stable and flat, representing the PZT resonance is “tracking” the laser signal. The laser control signal 514 is also shown. The ramping PZT image 502 and the locked (tracking engaged) image 503 are close-loop measurements. The ramping PZT shows the signals before locking is engaged. The locked (tracking engaged) shows the signals after the locking is engaged.

FIG. 5B illustrates laser stabilization with PZT sideband modulation of an AOM-free photonic integrated stabilization in accordance with an embodiment of the invention. The results are based on the stabilization circuit with a semiconductor laser and a coil reference cavity shown in FIG. 2A. The laser ramping image 504 shows the laser control signal 521, the error signal 522, the coil transmission 523, and the PZT transmission signal 524. The laser locked image 505 shows the error signal 522, the coil transmission signal 523, and the PZT transmission signal 524.

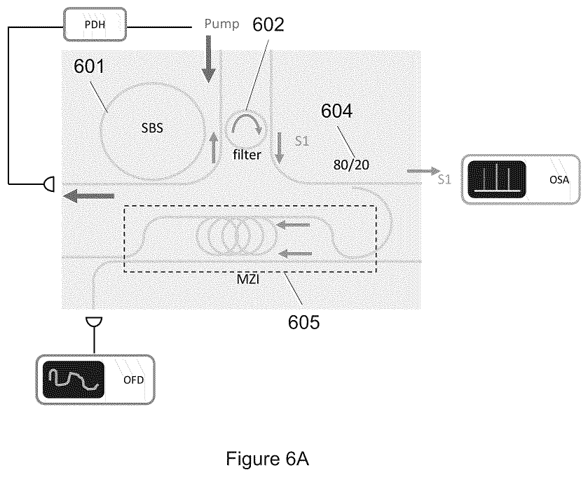

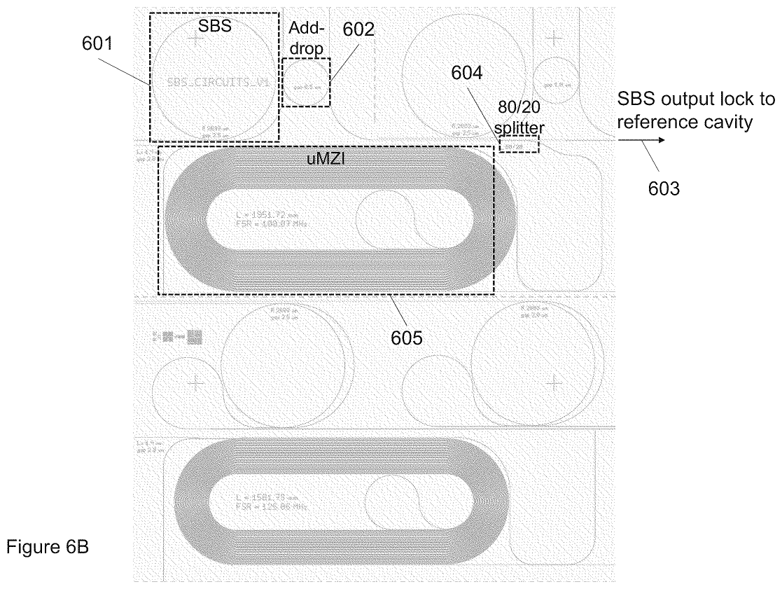

FIG. 6A illustrates an SBS laser photonic integrated circuit (PIC) layout in accordance with an embodiment of the invention. FIG. 6B illustrates an integration mask design for an SBS laser at 1550 nm in accordance with an embodiment of the invention. An SBS resonator 601 connects with an add-drop ring resonator 602. A PZT actuator and metal tuner can be deposited on the SBS resonator for SBS modulation. PZT actuator (not shown) can be deposited on the add-drop ring resonator 602 for filtering, sideband modulation and carrier tracking, which eliminate the use of AOM and EOM in the PIC. The SBS laser output can be locked to a reference cavity 603. The 80/20 splitter 604 can divide S1 into OFD and output. MZI 605 can be used as on chip OFD for frequency noise measurements. In FIG. 6A, the SBS resonator can have radius of about 2.690 mm. The add-drop ring for dropping S1 can have a radius of about 1.0 mm. On-chip 2-meter uMZI 605 can be used as OFD for S1 frequency noise measurement. TE₀ mode is 6 μm by 80 nm waveguide.

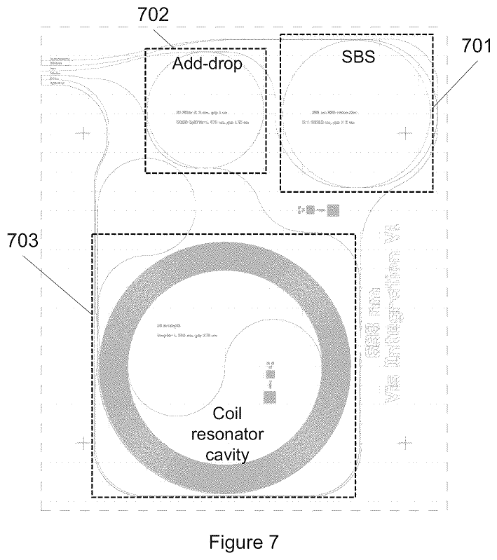

FIG. 7 illustrates an integration mask design for an SBS laser at 698 nm in accordance with an embodiment of the invention. An SBS resonator 701 connects with an add-drop ring resonator 702. A PZT actuator and metal tuner can be deposited on the SBS resonator for SBS modulation. PZT actuator (not shown) can be deposited on the add-drop ring resonator 702 for filtering, sideband modulation and carrier tracking, which eliminate the use of AOM and EOM in the PIC. The SBS laser output can be locked to a coil resonator 703 for cavity locking for on-chip laser stabilization.

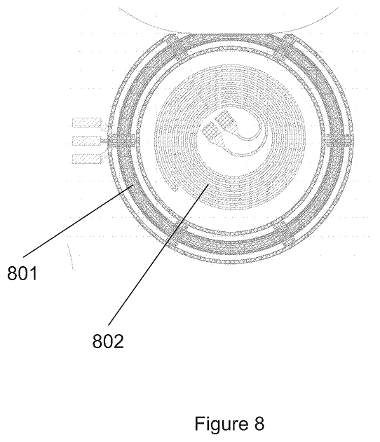

FIG. 8 illustrates a mask design for a thermo-optic modulator for laser stabilization in accordance with an embodiment of the invention. PZT actuators 801 and metal heater tuner 802 can be integrated on-chip for laser photonic integrated circuit.

### Doctrine of Equivalents

As can be inferred from the above discussion, the above-mentioned concepts can be implemented in a variety of arrangements in accordance with embodiments of the invention. Accordingly, although the present invention has been described in certain specific aspects, many additional modifications and variations would be apparent to those skilled in the art. It is therefore to be understood that the present invention may be practiced otherwise than specifically described. Thus, embodiments of the present invention should be considered in all respects as illustrative and not restrictive.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately,” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

What is claimed is:

1. A laser stabilization circuit comprising:
a tunable laser;
a modulator comprising an actuator and a resonator; wherein the modulator is a self-tracking optical modulator;
a three-port network comprising a low-frequency DC port, a high-frequency radio-frequency (RF) port, and a combined port;
a reference cavity;
a voltage-controlled oscillator (VCO); and
a first feedback loop and a second feedback loop;
wherein the first feedback loop connects with the modulator and applies a feedback signal to the modulator via the low-frequency DC port such that the modulator tracks a resonance of the laser without using an acousto-optic modulator (AOM);
wherein the second feedback loop connects with the reference cavity, the modulator, and the VCO; and the high-frequency RF port applies a high-frequency signal to the modulator such that the modulator functions as a double sideband modulator and the laser is Pound-Drever-Hall (PDH) locked to the reference cavity without using an electro-optic modulator (EOM); and
wherein the stabilization circuit modulates an output of the tunable laser.

2. The circuit of claim 1, wherein the modulator is a stress-optic modulator, a thermo-optic modulator, or an electro-optic modulator.

3. The circuit of claim 1, wherein the resonator is a ring resonator or a phase resonator.

4. The circuit of claim 3, wherein the ring resonator has a circular shape.

5. The circuit of claim 1, wherein the three-port network is an electrical network or an electrical optical network.

6. The circuit of claim 1, wherein the first feedback loop is a proportional integral derivative (PID) loop.

7. The circuit of claim 1, wherein the second feedback loop is a PID loop.

8. A laser stabilization circuit comprising:
a tunable laser;
a stress-optical modulator comprising an actuator and a ring resonator;
a three-port electrical network comprising a low-frequency DC port, a high-frequency radio-frequency (RF) port, and a combined port;
a reference cavity;
a voltage-controlled oscillator (VCO); and
a first proportional integral derivative (PID) loop and a second PID loop;
wherein the first PID loop connects with the stress-optical modulator and applies a feedback signal to the stress-optical modulator via the low-frequency DC port such that the stress-optical modulator tracks a resonance of the laser without using an acousto-optic modulator (AOM);
wherein the second PID loop connects with the reference cavity, the stress-optical modulator, and the VCO; and the high-frequency RF port applies a high-frequency signal to the stress-optical modulator such that the stress-optical modulator functions as a double sideband modulator and the laser is Pound-Drever-Hall (PDH) locked to the reference cavity without using an electro-optic modulator (EOM); and
wherein the stabilization circuit modulates an output of the tunable laser.

9. The circuit of claim 8, wherein the actuator is laterally and vertically offset from a core of the ring resonator and from an optical mode profile of the ring resonator such that the actuator does not appreciably affect a waveguide loss or a resonator quality factor (Q).

10. The circuit of claim 9, wherein the core of the ring resonator comprises a material selected from the group consisting of: silicon nitride, tantalum pentoxide, alumina oxide, and aluminum nitride.

11. The circuit of claim 8, wherein the actuator comprises lead zirconate titanate (PZT) and the ring resonator comprises silicon nitride, and the modulator functions at a wavelength selected from the group consisting of: a visible wavelength range from 400 nm to 750 nm, a near IR wavelength range from 700 nm to 2500 nm, and a mid IR wavelength range from 2500 nm to 25,000 nm.

12. The circuit of claim 8, wherein the actuator comprises PZT and the ring resonator comprises tantalum pentoxide, alumina oxide, or aluminum nitride, and the modulator functions at a wavelength range selected from the group consisting of: a far-UV wavelength range from 100 nm to 200 nm, a mid-UV wavelength range from 200 nm to 300 nm, a near UV wavelength range from 300 nm to 400 nm, and a visible, near IR and mid-IR wavelength range from 400 nm to 2350 nm.

13. The circuit of claim 8, wherein the tunable laser is selected from the group consisting of: a semiconductor laser, a stimulated Brillouin scattering (SBS) laser, a PZT-controlled SBS laser, an external cavity laser, a PZT-controlled external cavity laser, a distributed Bragg reflector (DBR) laser, and an external distributed Bragg reflector (EDBR) laser.

14. The circuit of claim 8, wherein the circuit is compatible with CMOS foundry fabrication process.

15. The circuit of claim 8, wherein the reference cavity is a coil reference cavity, an ultra-high Q reference cavity, or a miniature bulk micro-optic cavity.

16. The circuit of claim 15, wherein the coil reference cavity comprises a resonator selected from the group consisting of: a 2-meter on-chip coil resonator, a 4-meter on-chip coil resonator, a 6-meter on-chip coil resonator, an 8-meter on-chip coil resonator, and a 10-meter on-chip coil resonator.

17. The circuit of claim 15, wherein the ultra-high Q cavity has a Q of at least 40 million.

18. The circuit of claim 1, wherein a modulation bandwidth of the laser is from 1 kHz to 10 MHz.

19. A circuit comprising:
a tunable optical frequency comb (OFC);
a stress-optical modulator comprising an actuator and a ring resonator;
a three-port network comprising a low-frequency DC port, a high-frequency radio-frequency (RF) port, and a combined port;
a reference cavity;
a voltage-controlled oscillator (VCO); and
a first proportional integral derivative (PID) loop and a second PID loop;
wherein the first PID loop connects with the stress-optical modulator and applies a feedback signal to the stress-optical modulator via the low-frequency DC port such that the stress-optical modulator tracks a resonance of the OFC without using an acousto-optic modulator (AOM);
wherein the second PID loop connects with the reference cavity, the stress-optical modulator, and the VCO; and the high-frequency RF port applies a high-frequency signal to the stress-optical modulator such that the stress-optical modulator functions as a double sideband modulator and the OFC is Pound-Drever-Hall (PDH) locked to the reference cavity without using an electro-optic modulator (EOM); and
wherein the circuit modulates an output of the OFC.

20. The circuit of claim 19, wherein the actuator is laterally and vertically offset from a core of the ring resonator and from an optical mode profile of the ring resonator such that the actuator does not appreciably affect a waveguide loss or a resonator Q.

21. The circuit of claim 20, wherein the core of the ring resonator comprises a material selected from the group consisting of: silicon nitride, tantalum pentoxide, alumina oxide, and aluminum nitride.

22. The circuit of claim 19, wherein the actuator comprises lead zirconate titanate (PZT) and the ring resonator comprises silicon nitride, and the modulator functions at a wavelength selected from the group consisting of: a visible wavelength range from 400 nm to 750 nm, a near IR wavelength range from 700 nm to 2500 nm, and a mid IR wavelength range from 2500 nm to 25,000 nm.

23. The circuit of claim 19, wherein the actuator comprises PZT and the ring resonator comprises tantalum pentoxide, alumina oxide, or aluminum nitride, and the modulator functions at a wavelength range selected from the group consisting of: a far-UV wavelength range from 100 nm to 200 nm, a mid-UV wavelength range from 200 nm to 300 nm, a near UV wavelength range from 300 nm to 400 nm, and a visible, near IR and mid-IR wavelength range from 400 nm to 2350 nm.

24. The circuit of claim 19, wherein the circuit is compatible with CMOS foundry fabrication process.

25. The circuit of claim 19, wherein the reference cavity is a coil reference cavity, an ultra-high Q reference cavity, or a miniature bulk micro-optic cavity.

26. The circuit of claim 25, wherein the coil reference cavity comprises a resonator selected from the group consisting of: a 2-meter on-chip coil resonator, a 4-meter on-chip coil resonator, a 6-meter on-chip coil resonator, an 8-meter on-chip coil resonator, and a 10-meter on-chip coil resonator.

27. The circuit of claim 25, wherein the ultra-high Q cavity has a Q of at least 40 million.
